(19) United States
(12) Patent Application Publication
(10) Pub. No.: US 2010/0300874 A1
(43) Pub. Date: Dec. 2, 2010

(54) PATTERNING MAGNETIC RECORDING MEDIA WITH ION IMPLANTATION UTILIZING A COMBINATION OF HEAVY AND LIGHT ION SPECIES

(76) Inventors: David Shiao-Min Kuo, Palo Alto, CA (US); Dieter Weller, San Jose, CA (US); Jan-Ulrich Thiele, Sunnyvale, CA (US); Justin Hwu, Fremont, CA (US); Paritosh Rajora, Santa Clara, CA (US)

Correspondence Address: SEAGATE TECHNOLOGY Outside Counsel Dergosits;& Noah LLP, Three Embarcadero Center, Suite 410, San Francisco, CA, 94111, US

(21) Appl. No.: 12/473,510

(22) Filed: May 28, 2009

(51) Int. Cl. C23C 14/46

(52) U.S. Cl. 204/192.34

(57) ABSTRACT

A patterned magnetic layer is formed by bombardment of a masked high Mrt magnetic layer with a combination of both heavy ion species and light ion species. The method can be implemented as sequential process steps or in a single process step with the proper heavy/light ion species mixture. Advantageously, the combined heavy/light ion species bombardment method results in a patterned magnetic layer having high topographical uniformity across its surface.

### FIELD OF THE INVENTION

The present invention relates generally to magnetic recording media and, in particular, to the utilization of a combination of heavy ion species and light ion species in an implantation procedure to achieve a planarized patterned recording medium.

### BACKGROUND ART

Thin film magnetic recording discs and disc drives are conventionally employed for storing large amounts of data in magnetizable form. In the operation of a disc drive, a typical contact start/stop method involves a floating transducer head gliding at a predetermined distance from the surface of the recording disc due to dynamic pressure effects caused by air flow generated between the sliding surfaces of the transducer head and the disc. During reading and recording (writing) operations, the transducer head is maintained at a controlled distance from the recording surface, supported on a bearing of air as the disc rotates, such that the transducer head can be moved freely in both the circumferential direction and the radial direction, allowing data to be recorded on and retrieved from the surface of the recording disc at a desired position in a data zone.

In conventional hard disc drives, data are stored in terms of bits along tracks. In operation, the disc is rotated at relatively high speed and the magnetic head assembly is mounted on the end of a support or actuator arm that positions the head radially on the disc surface. If the actuator arm is held stationary, the magnetic head assembly passes over a circular path on the disc, i.e. over a track, and information can be read from or written to that track. Each concentric track has a unique radius. Reading and writing information from or to a specific track requires the magnetic head to be located above that track. By moving the actuator arm, the magnetic head assembly is moved radially on the disc surface between tracks.

Referring to FIGS. 1A and 1B, data are stored on a magnetic recording disc by patterning a thin film magnetic layer 22 formed on a non-magnetic substrate 10 using ion bombardment. Although, with the proper energy and dose, the magnetic layer 22 can be patterned by selective implantation with either a heavy ion species, e.g. argon, or a light ion species, e.g. B₂H₆, it has been found that, with a heavy ion species, there is enough sputter yield to cause material removal, which results in a surface depression in the implanted region 20, as shown in FIG. 1A. With a light ion species, implantation causes the magnetic layer material to swell, resulting in a surface protrusion in the implanted region 20, as shown in FIG. 1B. In either case, ion implantation results in residual topography in the implanted region 20 of the magnetic layer 22 that is undesirable for flyability.

Thus, there exists a continuing need for an efficient, economical fabrication technique that enables the patterning of a magnetic recording medium utilizing ion bombardment without adversely affecting the topography of the recording medium.

### SUMMARY OF THE INVENTION

The present invention combines implantation of heavy ion species and light ion species to form low Mrt regions in a high Mrt magnetic layer while leaving a surface without the substantial topography of the typical patterned magnetic layer design. The method can be implemented as sequential process steps or in a single process step with the proper gas mixture. For example, the method can be accomplished by sequential bombardment of the magnetic layer with a heavy ion species, e.g. argon, that causes etching, followed by bombardment with a light atom ion species, e.g. B₂H₆, that causes protrusion. Alternately, the light ion species, e.g. B₂H₆, can be implanted first to cause protrusion followed by bombardment with the heavy atom ion species, e.g. argon, to remove the protruding topography. Another alternate method is to mix a heavy ion species, e.g. argon, and a light ion species, e.g. B₂H₆, in a single implantation process. The preferred energy range of operation is 1-15 KeV and the preferred total implant dosage is in the range of 10E5-10E7.

Additional advantages and other features of the present invention will become readily apparent to those skilled in the art from the following detailed description of the invention, wherein only preferred embodiments are shown and described, by way of illustration of the best mode contemplated for carrying out the invention. As will be realized, the present invention is capable of other and different embodiments and its several details are capable of modifications in various obvious respects, all without departing from the present invention. Accordingly, the drawings and description provided herein should be regarded as illustrative, not restrictive.

### BRIEF DESCRIPTION OF THE DRAWINGS

FIG. 1A is a partial cross section drawing illustrating a depression that is formed in a low Mrt region of a magnetic layer by bombardment with a heavy ion species.

FIG. 1B is a partial cross section drawing illustrating a protrusion that is formed in a low Mrt region of a magnetic layer by bombardment with a light ion species.

FIG. 2 is a flow chart schematically illustrating a method of forming low Mrt regions in a high Mrt magnetic layer utilizing bombardment with a heavy ion species followed by bombardment with a light ion species, in accordance with the concepts of the present invention.

FIG. 3 is a flow chart schematically illustrating a method of forming low Mrt regions in a high Mrt magnetic layer utilizing bombardment with a light ion species followed by bombardment with a heavy ion species, in accordance with the concepts of the present invention.

FIG. 4 is a flow chart schematically illustrating a method of forming low Mrt regions in a high Mrt magnetic layer by bombardment with a mix of a heavy ion species and a light ion species, in accordance with the concepts of the present invention.

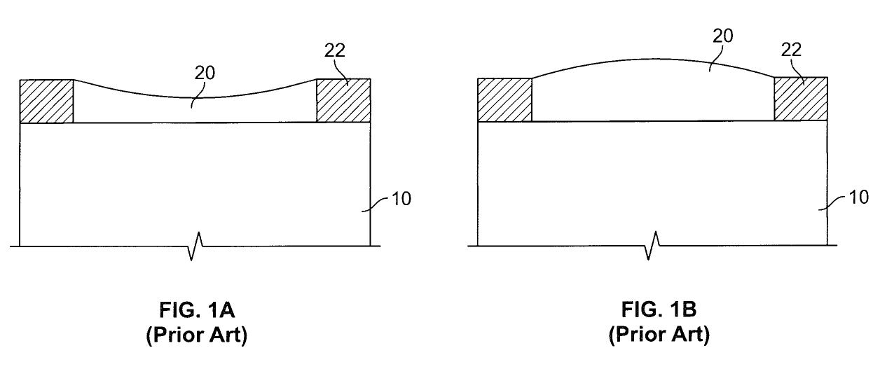

### DETAILED DESCRIPTION OF THE INVENTION

In forming a patterned magnetic layer in accordance with the concepts of the present invention, a non-magnetic substrate well known to those skilled in the art, e.g. a glass substrate, is initially selected. A film stack may then be formed on the non-magnetic substrate in the well known manner. In the embodiments of the invention disclosed herein, the film stack includes a magnetically “soft” underlayer (SUL) such as chromium or a chromium alloy that is sputter deposited on the non-magnetic substrate. A thin high chromium content CoCrTa intermediate layer is then sputter deposited on the SUL. A magnetically “hard” (high Mrt) layer is sputter deposited on the intermediate layer. Optionally, an overcoat layer, e.g. diamond-like carbon, may be formed on the magnetically “hard” layer. As is well known, the magnetically “hard” layer typically comprises a cobalt-based alloy, such as a cobalt-platinum-chromium alloy, and can further comprise several layers of cobalt alloys.

In accordance with the present invention, the magnetically “hard” layer is masked and then subjected to ion bombardment with both heavy ion species and light ion species to lower the Mrt of those regions of the magnetic layer that are exposed by openings in the mask. While it is preferred that the Mrt of the exposed regions be reduced to zero, at a minimum, the Mrt in the damage regions should be reduced to below 50 percent of the original Mrt of the magnetic layer. In accordance with the present invention, the masked magnetic layer is subjected to a combination of heavy ion species, i.e. an ion species having an atomic weight of greater than that of oxygen (e.g., argon), and light ion species, i.e. an ion species have an atomic weight of less than or equal to that of oxygen (e.g., B₂H₆). As discussed in greater detail below, the combination heavy ion bombardment and light ion bombardment can be implemented as sequential process steps or in a single process step.

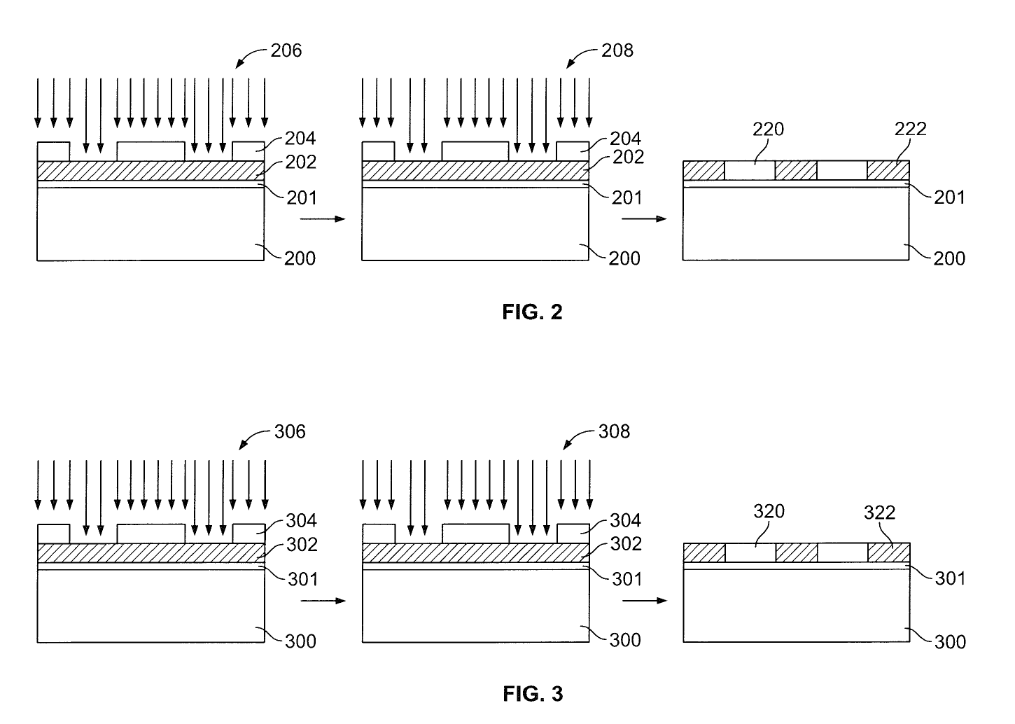

The present invention contemplates that the high Mrt magnetic layer is selectively masked, i.e. the magnetic layer has exposed regions and regions that are covered or otherwise protected by, for example, a photoresist layer having suitable thickness. By exposing a masked high Mrt magnetic layer to a combination of heavy/light ion bombardment, the present invention advantageously achieves a patterned magnetic layer having discrete low Mrt regions and high Mrt regions formed therein. In flow diagrams illustrating embodiments of the methodology of the present invention, each of FIGS. 2, 3 and 4 shows a high Mrt magnetic layer formed on an underlying substrate (the term “substrate” being meant to include a non-magnetic substrate and overlying film stack, if any) and masked by resist or stencil, it being understood that the mask represents any desired pattern.

In accordance with the embodiment of the invention shown in the FIG. 2, a high Mrt magnetic layer 202 is formed on a non-magnetic substrate 200, e.g. a glass substrate, which may include a film stack 201 formed on its upper surface. The film stack may comprise a SUL and an intermediate layer. Optionally, a layer of diamond-like carbon (not shown) is formed on the high Mrt magnetic layer 202. The magnetic layer 202 is covered by a patterned mask 204 and is first bombarded with a heavy ion species 206. The heavy ion species may be selected from the group consisting of argon, krypton, xenon, chromium or any subset thereof. The masked magnetic layer 202 is subjected to one or more bombardments of the heavy ion species at an implantation energy of about 1-15 KeV to provide low Mrt regions in the exposed areas of the magnetic layer 202. Following the heavy ion bombardment, the masked magnetic layer 202 is bombarded with a light ion species 208. The light ion species may be selected from the group consisting of hydrogen, helium, B₂H₆, nitrogen, oxygen or any subset thereof. The masked magnetic layer 202 is subjected to one or more bombardments of the light ion species at an implantation energy of about 1-15 KeV. Those skilled in the art will appreciate that the implant dosages and the implant times for both the heavy ion species bombardment and the light ion bombardment can be coordinated to provide the desired planarity of the upper surface of the magnetic layer 202. After the two-step ion bombardment sequence, the mask 204, e.g. a photoresist, is removed to expose a magnetic layer having discretely patterned low Mrt regions 220 and high Mrt regions 222 formed therein without adversely affecting the topography of the magnetic layer. The photoresist may be removed by conventional photoresist removal techniques. Advantageously, the combined heavy/light ion bombardment method in accordance with the FIG. 2 embodiment of the invention results in a patterned magnetic layer having high topographical uniformity across its surface.

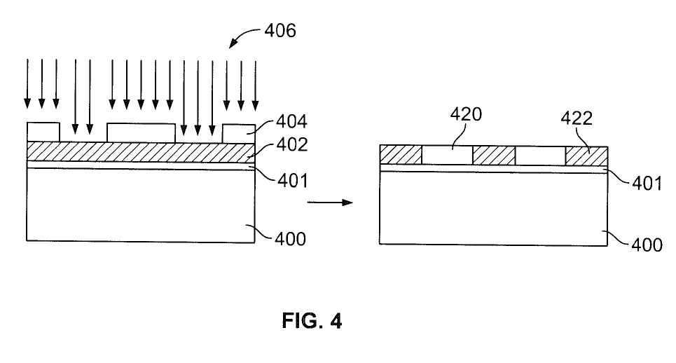

In the FIG. 3 patterning method, a high Mrt magnetic layer 302 is formed on a non-magnetic substrate 300, e.g. a glass substrate, that may have a film stack 301 formed thereon, the film stack comprising a SUL and intermediate layer. Optionally, the high Mrt magnetic layer may have a layer of diamond-like carbon (not shown) formed thereon. The high Mrt magnetic layer 302 is covered by a patterned mask 304, e.g. photoresist, and first bombarded with a light ion species 306. The light ions may be selected from the group consisting of hydrogen, helium, B₂H₆, nitrogen, oxygen or any subset thereof. The masked magnetic layer 302 is subjected to one or more ion bombardments of the light ion species at an implantation energy of about 1-15 KeV to provide low Mrt regions in the exposed areas of the magnetic layer 302. Following the light ion bombardment, the masked magnetic layer 302 is bombarded with a heavy ion species 308. The heavy ions may be selected from the group consisting of argon, krypton, xenon, chromium or any subset thereof. The masked magnetic layer 302 is subjected to one or more ion bombardments of heavy ions at an implant energy of about 1-15 KeV. As in the FIG. 2 methodology, those skilled in the art will appreciate that the implant dosage and the implant time for both the light ion bombardment and the heavy ion bombardment can be coordinated to provide the desired planarity of the upper surface of the magnetic layer 302. After the light/heavy ion bombardment sequence, the mask 304 is removed to expose a magnetic layer having discretely patterned low Mrt regions 320 and high Mrt regions 322 formed therein without adversely affecting the topography of the layer 302.

In the FIG. 4 patterning method, a high Mrt magnetic layer 402 is formed on a non-magnetic substrate 400, e.g. a glass substrate, that may have a film stack 401 formed thereon, the film stack comprising a SUL and intermediate layer. Optionally, the magnetic layer 402 has an overcoat layer of diamond-like carbon (not shown) formed thereon in the well known manner. The high Mrt magnetic layer 402 is covered by a patterned mask 404 and bombarded with a mix 406 of heavy ion species and light ion species, as defined above. The masked magnetic layer 402 is subjected to one or more bombardments of the heavy/light ion mix at an implant energy of about 1-15 KeV. As will be appreciated by those skilled in the art, the composition of the heavy/light ion mix, the implant dosage and the implant time can be coordinated to provide the desired planarity of the upper surface of the magnetic layer 402. The mask 404 is then removed to expose a magnetic layer having discretely patterned low Mrt regions 420 and high Mrt regions 422 formed therein without adversely affecting the topography of the layer.

Only preferred embodiments of the present invention are shown and described in the present disclosure. It is to be understood that the present invention is capable of use in various other combinations and environments and is capable of changes and modifications within the scope of the inventive concept as expressed herein.

What is claimed is:

1. A method of patterning a high Mrt magnetic layer, the method comprising: bombarding exposed regions of a masked high Mrt magnetic layer with a combination of heavy ion species that result in etching of the exposed regions and light ion species that result in swelling of the exposed regions, the combination bombardment resulting in the formation of substantially planar low Mrt regions in the high Mrt magnetic layer.

2. The method of claim 1, wherein the exposed regions of the masked high Mrt magnetic layer are bombarded first with the heavy ion species followed by bombardment with the light ion species.

3. The method of claim 1, wherein the exposed regions of the masked high Mrt magnetic layer are bombarded first with the light ion species followed by bombardment with the heavy ions species.

4. The method of claim 1, wherein the exposed regions of the masked high Mrt magnetic layer are bombarded with a mix of the heavy ion species and the light ion species.

5. The method of claim 1, wherein the heavy ion species comprises argon and the light ion species comprises B₂H₆.
